(19) United States
(12) Patent Application Publication
(10) Pub. No.: US 2018/0040855 A1
(43) Pub. Date: Feb. 8, 2018

(54) DEPOSITION MASK FOR MAKING OLED DISPLAY PANEL

(71) Applicant: HON HAI PRECISION INDUSTRY CO., LTD., New Taipei (TW)

(72) Inventor: JEN-JIE CHEN, New Taipei (TW)

(21) Appl. No.: 15/604,785

(22) Filed: May 25, 2017

Related U.S. Application Data
(60) Provisional application No. 62/370,729, filed on Aug. 4, 2016.

(51) Int. Cl. H01L 51/56; C23C 14/04; H01L 51/00

(52) U.S. Cl. CPC H01L 51/56; H01L 51/0002; C23C 14/042

(57) ABSTRACT

A mask is configured for depositing an organic light emitting layer of an OLED display panel. The mask includes a supporting plate and a plurality of mask units on a surface of the supporting plate. The supporting plate defines a plurality of through holes. Each mask unit covers one of the through holes and defines a plurality of openings. Each mask unit includes a center portion and an edge portion located at a periphery of the center portion and surrounding the center portion. In each mask unit, the dimensions of the openings gradually decrease along a direction from the edge portion towards the center portion to restrict the shapes and dimensions of pixel forms deposited.

### CROSS-REFERENCE TO RELATED APPLICATIONS

This application claims priority from U.S. provisional application Ser. No. 62/370,729 filed on Aug. 4, 2016 which is incorporated herein by reference.

### FIELD

The subject matter herein generally relates to a deposition mask for depositing an organic light emitting layer.

### BACKGROUND

Display devices, particularly organic light-emitting diode (OLED) display devices, are manufactured by forming an organic light emitting layer on a substrate (such as thin film transistor substrate) through vapor deposition. Generally, a deposition mask is required during deposition of the organic light emitting layer. A plurality of openings is defined in the deposition mask. Then the evaporated material from an evaporation source passes through the openings to be deposited on the substrate. Each opening corresponds to one subpixel of the OLED display panel. Generally, a dimension of each of the openings is designed to be equal to a dimension of the sub-pixel. However, some sub-pixels formed by using the deposition mask have dimensions that are greater than the designed dimensions. For example, when a desired pixel pattern is designed to have a width of x μm and a length of y μm. Using the deposition mask and evaporation process above creates a shadow effect in sub-pixel patterns where a sub-pixel pattern has a width larger than the defined x μm and a length larger than the defined y μm. Therefore, there is need to improve the process of creating sub-pixel patterns to improve the properties and performance of a display device.

### BRIEF DESCRIPTION OF THE DRAWINGS

Implementations of the present technology will now be described, by way of example only, with reference to the attached figures.

FIG. 1 is a plan view of a first exemplary embodiment of a deposition mask.

FIG. 2 is a cross-sectional view of the deposition mask of FIG. 1 along line II-II.

FIG. 3 is a plan view of a mask unit of the deposition mask of FIG. 1.

FIG. 4 is a plan view of a second exemplary embodiment of a deposition mask.

FIG. 5 is a cross-sectional view of the deposition mask of FIG. 4 along line V-V.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

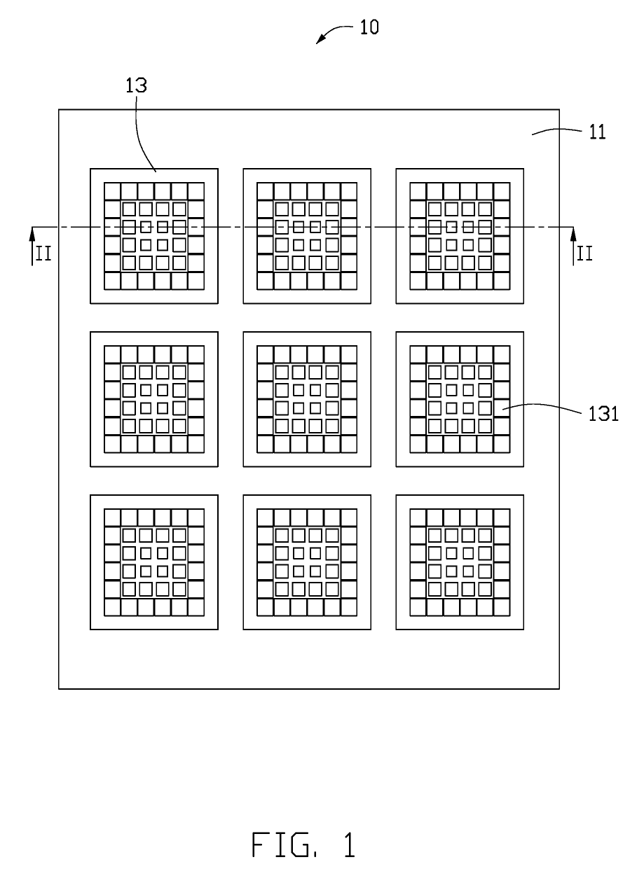

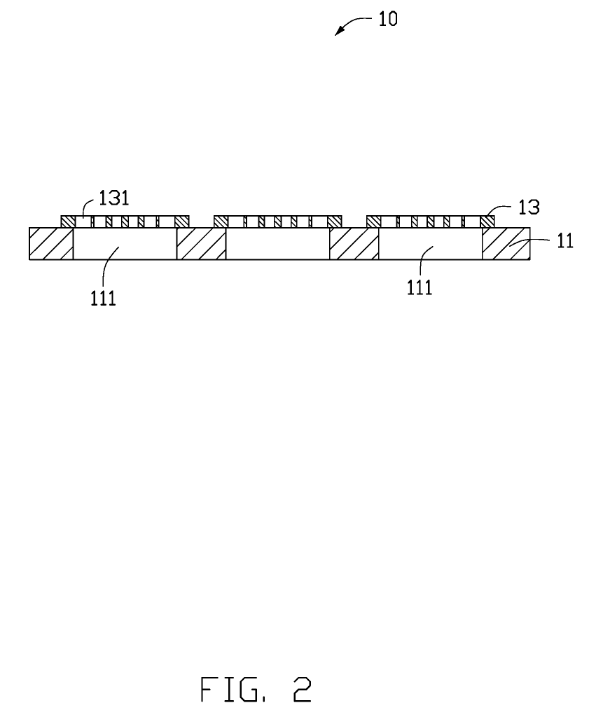

FIG. 1 and FIG. 2 illustrate a first exemplary embodiment of a deposition mask 10. The deposition mask 10 includes a supporting plate 11 and a plurality of mask units 13 coupled to a surface of the supporting plate 11. The supporting plate 11 is configured to support the plurality of mask units 13. Each of the plurality of mask units 13 is spaced apart from one another. The supporting plate 11 defines a plurality of through holes 111. Each through hole 111 corresponds to one of the mask units 13. A dimension of each through hole 111 is smaller than a dimension of each mask unit 13. Thus, each mask unit 13 can completely cover over one of the through holes 111. Moreover, the through holes 111 are arranged in an array, and thus the mask units 13 covering the through holes 111 of the supporting plate 11 are also arranged in an array on the supporting plate 11.

The supporting plate 11 is made of a metal or an alloy. In an exemplary embodiment, the supporting plate 11 may be made of a metal or alloy having magnetic properties. For example, the supporting plate 11 is made of an invar alloy. Each mask unit 13 can be made of a plastic, and the plastic can be one selected from a group consisting of: polyimide (PI), polyethylene terephthalate (PET), polycarbonate (PC), ethylene (PE), poly ether ether ketone (PEEK), polyetherimide (PEI), polyamide (PA), poly tetra fluoro ethylene (PTFE), poly propylene (PP), poly phenilen sulfide (PPS), poly ethylene naphthalate (PEN), and poly propylene (PP).

In an exemplary embodiment, each mask unit 13 is substantially rectangular. Each mask unit 13 defines a plurality of openings 131, each opening 131 being spaced apart from one another. FIGS. 1-3 show a number of the plurality of openings 131. The plurality of openings 131 extend through the mask unit 13. As shown in FIG. 2, each opening 131 of the mask unit 13 is adjacent to and air communicatively with each corresponding through hole 111. In this exemplary embodiment, each opening 131 is substantially rectangular.

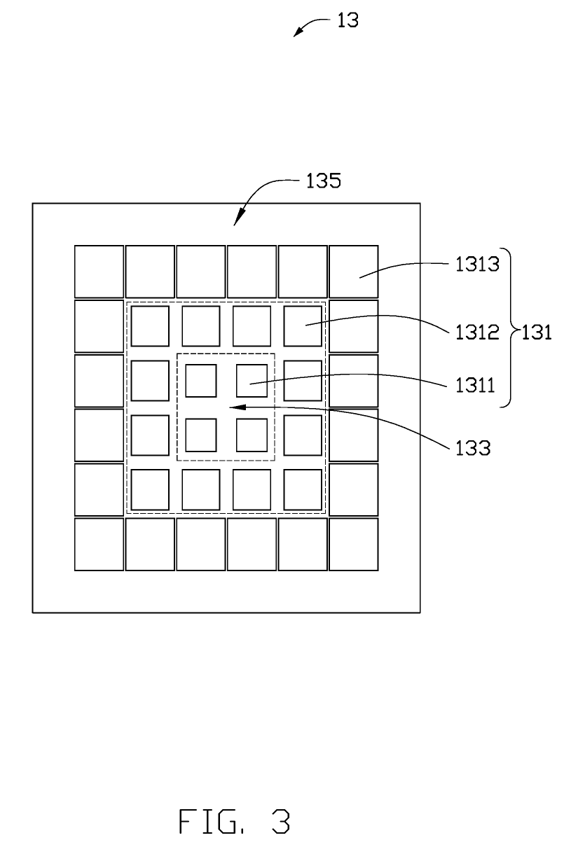

As shown in FIG. 3, each mask unit 13 includes a center portion 133 and an edge portion 135 located at a periphery of the center portion 133 and surrounding the center portion 133. In each mask unit 13, the dimensions of the openings 131 gradually decrease along a direction from the edge portion 135 towards the center portion 133.

As shown in FIG. 3, in this exemplary embodiment, the openings 131 in one single mask unit 13 comprise three types of openings 131 along a direction from the edge portion 135 towards the center portion 133. The openings 131 includes a plurality of first openings 1311 located in the center portion 133, a plurality of third openings 1313 located in the edge portion 135, and a plurality of second openings 1312 located between the center portion 133 and the edge portion 135. Each first opening 1311 has a dimension that is smaller than a dimension of each second opening 1312, and each second opening 1312 has a dimension that is smaller than a dimension of each third opening 1313. The dimension of each third opening 1313 is substantially equal to a required dimension of one sub-pixel of the OLED display panel to be formed. That is, a dimension of the openings 131 having the largest dimension in a single mask unit 13 is substantially equal to a required dimension of one sub-pixel of the OLED display panel to be formed.

When depositing an organic light emitting layer on a substrate (not shown), such as thin film transistor substrate, the substrate is located at a side of the deposition mask 10 having the mask units 13. Evaporated material from an evaporation source passes through the through hole 111 and the openings 131 to be deposited on the substrate. Each opening 131 corresponds to the form of one sub-pixel of the OLED display panel. By using the deposition mask 10 herein disclosed, the shadow effect can be effectively reduced or eliminated.

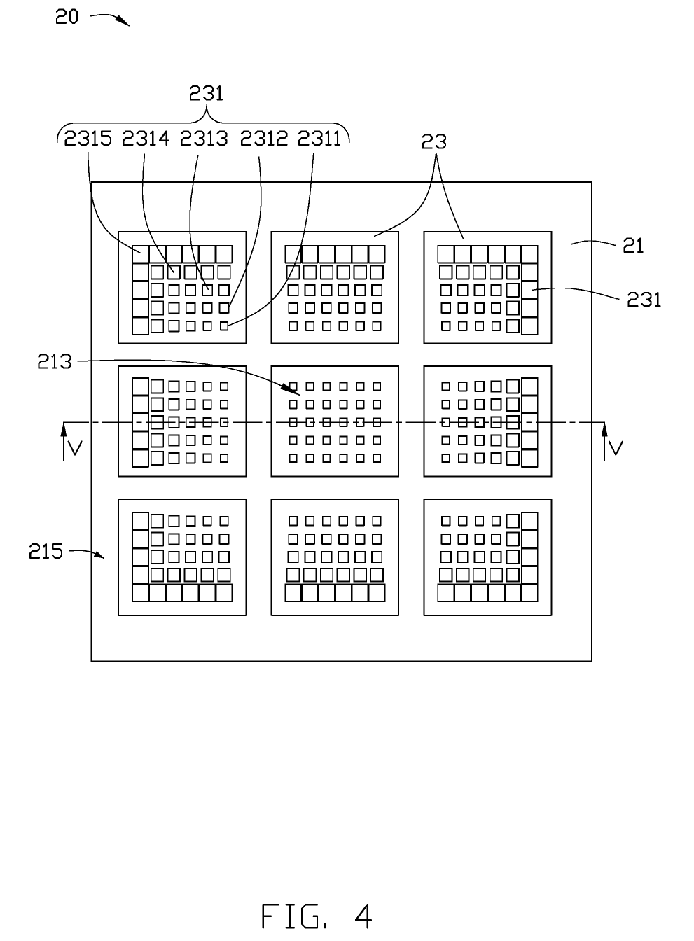

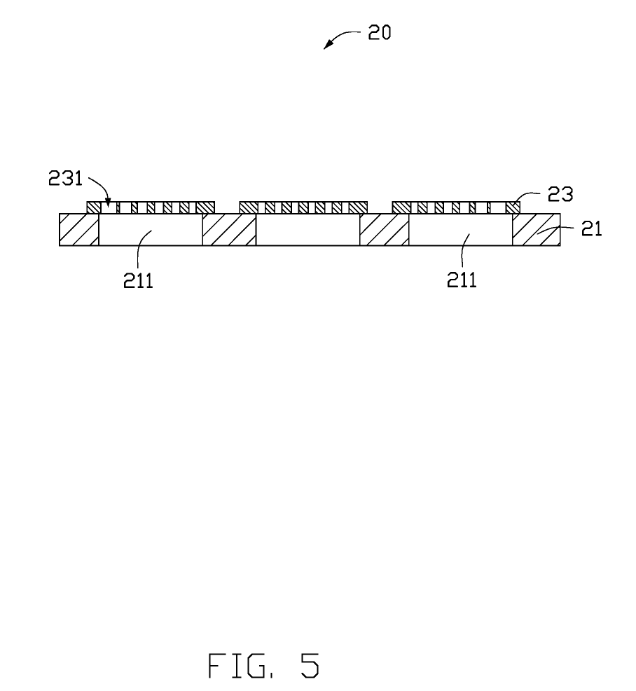

FIG. 4 and FIG. 5 illustrates a second exemplary embodiment of a deposition mask 20. The deposition mask 20 includes a supporting plate 21 and a plurality of mask units 23 coupled to a surface of the supporting plate 21. Each of the plurality of mask units 23 is spaced apart from one another. The supporting plate 21 is configured to support the mask units 23. The supporting plate 21 defines a plurality of through holes 211. Each through hole 211 corresponds to one of the mask units 23. The dimension of each through hole 211 is smaller than a dimension of each mask unit 23. Thus, each mask unit 23 can completely cover one of the through holes 211. Moreover, the through holes 211 are arranged in an array, and thus the mask units 23 covering the through holes 211 of the supporting plate 21 are also arranged in an array on the supporting plate 21.

The supporting plate 21 is made of a metal or an alloy. In an exemplary embodiment, the supporting plate 21 may be made of a metal or alloy having magnetic properties. For example, the supporting plate 21 is made of an invar alloy. Each mask unit 23 can be made of one selected from a group consisting of PI, PET, PC, PE, PEEK, PEI, PA, PTFE, PP, PPS, PEN, and PP.

In an exemplary embodiment, each mask unit 23 is substantially rectangular. Each mask unit 23 defines a plurality of openings 231. Each opening 231 is spaced apart from one another. The plurality of openings 231 extends through the mask unit 23. As shown in FIG. 5, each opening 231 of the mask unit 23 is adjacent to and air communicatively with each corresponding through holes 211. In this exemplary embodiment, each opening 231 is rectangular.

The supporting plate 21 includes a center portion 213 and an edge portion 215 located at a periphery of the center portion 213 and surrounding the center portion 213. In the deposition mask 20, the dimensions of the openings 131 gradually decrease along a direction from the edge portion 215 towards the center portion 213.

As shown in FIG. 4, in this exemplary embodiment, the openings 231 in the entire deposition mask 20 comprise five types of openings 231 along a direction from the edge portion 215 towards the center portion 213. The openings 231 includes a plurality of first openings 2311 located in the center portion 213, a plurality of fifth openings 2315 located in the edge portion 215, and a plurality of second openings 2312, a plurality of third openings 2313, and a plurality of fourth openings 2314 located between the center portion 213 and the edge portion 215. The plurality of second openings 2312 is located at a periphery of the first openings 2311 and surrounds the first openings 2311. The plurality of third openings 2313 is located at a periphery of the second openings 2312 and surrounds the second openings 2312. The plurality of fourth openings 2314 is located at a periphery of the third openings 2313 and surrounds the third openings 2313. The plurality of fifth openings 2315 is located at a periphery of the fourth openings 2314 and surrounds the fourth openings 2314. Each first opening 2311 has a dimension that is smaller than a dimension of each second opening 2312, and each second opening 2312 has a dimension that is smaller than a dimension of each third opening 2313. Each third opening 2313 has a dimension that is smaller than a dimension of each fourth opening 2314 and each fourth opening 2314 has a dimension that is smaller than a dimension of each fifth opening 2315. The dimension of each fifth opening 2315 is substantially equal to the dimension of one sub-pixel of the OLED display panel. In a single mask unit 23, the dimensions of the openings 231 gradually decrease along a direction from edge portion 215 of the deposition mask 20 towards the center portion 213 of the deposition mask 20.

When an organic light emitting layer is deposited on a substrate (not shown), such as thin film transistor substrate, the substrate is located at a side of the deposition mask 20 having the mask units 23. Evaporated material from an evaporation source passes through the through hole 211 and the openings 231, and reaches the substrate. Each opening corresponds to the form of one sub-pixel of the OLED display panel. By using this deposition mask 20, the shadow effect can be effectively reduced.

The embodiments shown and described above are only examples. Many details are often found in the art such as other features of a display device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A deposition mask, comprising:
a supporting plate defining a plurality of through holes; and
a plurality of mask units on a surface of the supporting plate, each of the plurality of mask units covering one of the plurality of through holes and defining a plurality of openings, each of the plurality of openings extending through the mask unit to be adjacent to and air communicating with the through holes, each of the plurality of mask units comprising a center portion and an edge portion located at a peripheral of the center portion and surrounding the center portion;
wherein, in at least one mask unit, the dimensions of the openings gradually decrease along a direction from the edge portion towards the center portion.

2. The deposition mask of claim 1, wherein the supporting plate is made of a metal or an alloy.

3. The deposition mask of claim 1, wherein the supporting plate is made of a metal having a magnetic property or an alloy having a magnetic property.

4. The deposition mask of claim 1, wherein each mask unit is made of one selected from a group consisting of: poly imide (PI), polyethylene terephthalate (PET), poly carbonate (PC), ethylene (PE), poly ether ether ketone (PEEK), poly etherimide (PEI), poly amide (PA), poly tetra fluoro ethylene (PTFE), poly propylene (PP), poly phenilen sulfide (PPS), poly ethylene naphthalate (PEN), and poly propylene (PP).

5. The mask of claim 1, wherein the plurality of mask units is arranged in an array.

6. The mask of claim 1, wherein the plurality of opening is arranged in an array.

7. A deposition mask, comprising:
a supporting plate defining a plurality of through holes, the supporting plate comprising a center portion and an edge portion located at a peripheral of the center portion and surrounding the center portion; and
a plurality of mask units on a surface of the supporting plate, each of the plurality of mask units covering one of the plurality of through holes and defining a plurality of openings, each of the plurality of openings extending through the mask unit to be adjacent to and air communicating with the through holes;;
wherein the dimensions of the openings gradually decrease along a direction from the edge portion towards the center portion.

8. The deposition mask of claim 7, wherein the supporting plate is made of a metal or an alloy.

9. The deposition mask of claim 7, wherein the supporting plate is made of a metal having a magnetic property or an alloy having a magnetic property.

10. The deposition mask of claim 7, wherein each mask unit is made of one selected from a group consisting of poly imide (PI), polyethylene terephthalate (PET), poly carbonate (PC), ethylene (PE), poly ether ether ketone (PEEK), poly etherimide (PEI), poly amide (PA), poly tetra fluoro ethylene (PTFE), poly propylene (PP), poly phenilen sulfide (PPS), poly ethylene naphthalate (PEN), and poly propylene (PP).

11. The deposition mask of claim 7, wherein the plurality of mask units is arranged in an array.

12. The deposition mask of claim 7, wherein the plurality of opening is arranged in an array.

13. A deposition mask for vapor deposition of an organic light emitting layer of an OLED display panel, the OLED display panel comprising a plurality of sub-pixel, the deposition mask comprising:
a supporting plate defining a plurality of through holes; and
a plurality of mask units on a surface of the supporting plate, each of the plurality of mask units covering one of the plurality of through holes and defining a plurality of openings, each of the plurality of openings extending through the mask unit to be adjacent to and air communicating with the through holes, each of the plurality of mask units comprising a center portion and an edge portion located at a peripheral of the center portion and surrounding the center portion;
wherein in at least one mask unit, the dimensions of the openings gradually decrease along a direction from the edge portion towards the center portion, and
wherein a dimension of each of the openings having the largest dimension in a single mask unit is substantially equal to a required dimension of one sub-pixel of the OLED display panel to be formed by using the mask unit.

14. The deposition mask of claim 13, wherein the supporting plate is made of a metal or an alloy.

15. The deposition mask of claim 13, wherein each mask unit is made of a plastic.
